(19) United States
(12) Patent Application Publication
(10) Pub. No.: US 2008/0264466 A1
(43) Pub. Date: Oct. 30, 2008

(54) Layer Arrangement for Darkening a Transparent Pane

(76) Inventor: Ismail Cuma, Munchen (DE)

Correspondence Address: WILLIAM E. BEAUMONT, 1901 L. STREET NW, SUITE 800, WASHINGTON, DC, 20036, US

(21) Appl. No.: 12/090,067

(22) PCT Filed: Oct. 13, 2006
(86) PCT No.: PCT/DE2006/001814

§ 371 Date: Apr. 11, 2008

(30) Foreign Application Priority Data
Oct. 13, 2005 (DE) 10 2005 049 081.6

(51) Int. Cl. H01L 31/042

(52) U.S. Cl. 136/244

(57) ABSTRACT

A layer arrangement for darkening a transparent pane (4), in particular a motor vehicle window pane, so as to offer protection from incident light (5), comprises: at least one first photovoltaic layer (1; 1a, 1b) with a high degree of light absorption, at least one second photovoltaic layer (2) with a high degree of light absorption and a high degree of light reflection, arranged behind the at least one first photovoltaic layer (1; 1a, 1b), in the direction of incidence of the incident light (5), at least one active insulating layer (3; 3a, 3b) with an electrically variable degree of darkening, and arranged behind the at least one second photovoltaic layer (2), in the direction of incidence of the incident light (5), and a controller for electrically controlling the degree of darkening of the at least one active insulation layer (3; 3a, 3b) using the electric energy generated by the at least one first photovoltaic layer (1; 1a, 1b) and/or the at least one second photovoltaic layer (2).

The present invention relates to a layer arrangement for darkening a transparent pane or film, in particular a motor vehicle pane, in order to afford protection from incident light.

Although applicable to any desired panes, the present invention and the problem area on which it is based will be explained in more detail with regard to a motor vehicle pane, and in particular with regard to a windshield of a motor vehicle.

In order to prevent the incidence of light through a transparent pane into the eyes of persons driving or using a motor vehicle, devices have existed hitherto such as e.g. sun visors, sun protection roller blinds, dark adhesive films for transparent panes, tinted panes, antiglare flaps or sunglasses.

However, such devices all have specific disadvantages, such as e.g. invariable light attenuation, complete darkening of the entire region of a transparent pane by coloration or tinting, complete optical masking by the antiglare means, such as a pair of sunglasses, which brings about darkening even at undesired regions. Further disadvantages arise from the unwieldy handling and the disturbing design of some of these devices.

In addition, the sun visor or the sun roller blind in a motor vehicle takes the upper field of view completely from the visible region, such that signals or the like can be overlooked. This can lead to dangerous traffic situations.

A further disadvantage of transparent and/or tinted panes is that they greatly heat up the interior of the motor vehicle upon intensive insulation, in particular in the case of motor vehicles parked in the open during the day, especially as conventional sun protection means only partly cover the pane areas.

Furthermore, protection against looking through from the outside into the interior of the motor vehicle can currently be achieved only by means of internal mirroring arrangements, i.e. semitransparent mirror surfaces, by means of intensive tinting of the panes by means of interior curtains or louvers. Removing this protection whilst traveling for safety-relevant panes is impossible in the case of mirrored and tinted panes and can be achieved only in a manner that takes a long time and with movements distracting attention from traffic events in the case of mechanical aids such as sun visors, roller blinds or louvers.

The document DE 2 421 486 B2 discloses an antiglare device in which, in a partial region of a windshield of a motor vehicle, the light transmissivity can be regulated at high speed depending on the brightness of an external light source. In this case, a phototransistor arranged outside the pane detects the light from an oncoming vehicle. The windshield is formed in that region with a liquid crystal whose light transmissivity is controlled by the phototransistor. Since the phototransistor does not recognize any directional dependence for the incident light, it detects the entire ambient light and thus darkens the windshield region provided.

What has proved to be disadvantageous about this approach, however, is the fact that the phototransistor for detecting the incident light has to be fitted outside the pane and thus in a laborious and cost-intensive manner. Furthermore, additional energy sources are necessary for driving the liquid crystal.

The present invention is based on the object of specifying a device for protecting a transparent pane or film from incident light which can be produced in a cost-effective manner, which can be integrated in a simple manner and the protective effect of which can be controlled depending on the incident light.

This object is achieved according to the invention by means of the layer arrangement according to the features of patent claim 1.

The idea on which the present invention is based consists in the fact that the layer arrangement for darkening a transparent pane in order to afford protection from incident light has at least one first photovoltaic layer with a high degree of light absorption; at least one second photovoltaic layer with a high degree of light absorption and a high degree of light reflection, arranged behind the at least one first photovoltaic layer in the direction of the incident light; at least one active insulation layer with an electrically variable degree of darkening, arranged behind the at least one second photovoltaic layer in the direction of the incident light; and a control device for electrically controlling the degree of darkening of the at least one active insulation layer using the electrical energy generated by the at least one first photovoltaic layer and/or the at least one second photovoltaic layer.

Consequently, the present invention has the advantage over the known approaches in accordance with the prior art that no additional energy sources are necessary for driving the at least one active insulation layer for altering the degree of darkening thereof, since the electrical energy is generated by the photovoltaic layers and used for the driving. Furthermore, the photovoltaic layers have a double function since, firstly, they convert the incident light radiation into electrical energy and, secondly, they already absorb and/or reflect a certain percentage of the incident radiation and therefore provide for a predetermine darkening of the transparent pane.

In addition, the layer arrangement of the present invention can be formed as a thin film which can be fitted on a pane to be darkened, for example, in a simple and cost-effective manner.

Advantageous configurations and improvements of the layer arrangement specified in patent claim 1 are found in the subclaims.

In accordance with one preferred development, a plurality, for example two or three, of first photovoltaic layers are provided successively in order to increase the total quantity of light absorbed. As a result, firstly, a predetermined darkening is already provided and, secondly, a sufficient quantity of electrical energy is provided.

In accordance with a further preferred development, a plurality, for example two or three, of first photovoltaic layers are provided successively in order to increase the total quantity of light (photons, light quanta) as a result, it is likewise possible to increase the degree of darkening and the quantity of electrical energy generated.

In accordance with a further preferred exemplary embodiment, the at least one photovoltaic layer and/or the at least one second voltaic layer are in each case composed of at least one suitably doped semiconductor material, for example a doped silicon, doped germanium or the like. The material of the at least one first photovoltaic layer has a high degree of light absorption, in particular, the material of the at least one second photovoltaic layer preferably having a high degree of light absorption and a high degree of light reflection in such a way that reflected light is once again reflected through the at least one first photovoltaic layer in order to generate additional electrical energy.

According to a further preferred development, the at least one first photovoltaic layer and/or the at least one second photovoltaic layer in each case have a nano- and/or picomaterial and/or an even smaller material. As a result the photovoltaic layers can be made finer and in improved fashion in such a way that the quantity of light absorbed and thus the current generated and the degree of darkening can be increased in comparison with a configuration with a micromaterial.

Advantageously, a plurality, for example two or three, of active insulation layers are provided successively in order to increase the total degree of darkening. Advantageously, all the insulation layers are driven by a common control device depending on the incident light using the energy generated at the photovoltaic layers.

Preferably, the at least one active insulation layer is formed as a semiconductor layer. By way of example, the active insulation layer can be formed in the form of an organic light emitting diode (OLED), in the form of a light emitting diode (OLED), an LCD and/or a mixture of these substances provided. Organic light emitting diodes of this type are good insulators and particularly suitable for darkening. The at least one active insulation layer can advantageously have a nano- and/or a picomaterial and/or an even smaller material.

In accordance with a further preferred exemplary embodiment, the layer arrangement can be fixed on a transparent pane, for example by means of a suitable adhesive bonding connection. As an alternative, the layer arrangement can also be integrated in a pane; by way of example, the layer arrangement can be laminated or embedded in the pane.

The invention is explained in more detail below on the basis of exemplary embodiments with reference to the accompanying figures of the drawing.

In the figures:

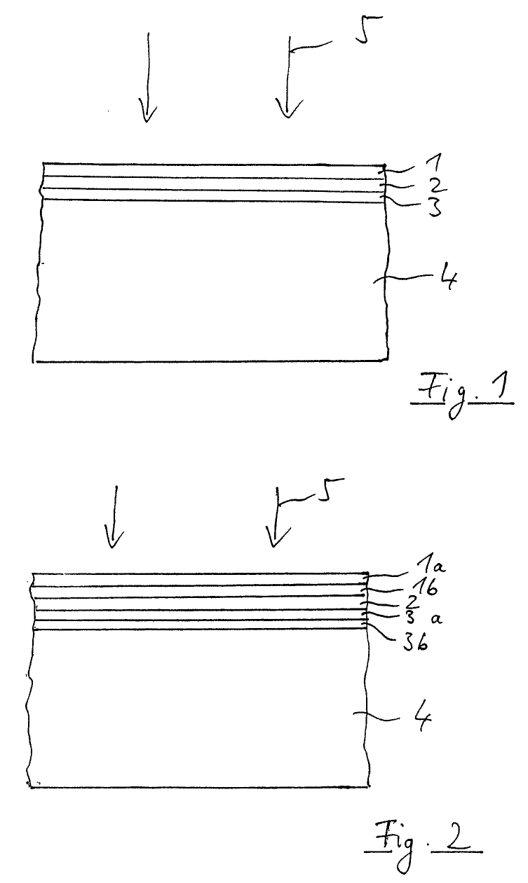

FIG. 1 shows a cross-sectional view of a layer arrangement applied on a pane in accordance with a first preferred exemplary embodiment of the present invention; and

FIG. 2 shows a cross-sectional view of a layer arrangement applied on a pane in accordance with a second preferred exemplary embodiment of the present invention.

In the figures, the same reference symbols designate identical or functionally identical components unless indicated to the contrary.

The figures illustrate cross-sectional view of layer arrangements according to the invention in accordance with preferred exemplary of the present invention, which are adhesively bonded on a transparent pane 4 of a motor vehicle preferably by means of a suitable adhesive. In the exemplary embodiments, the arrows identified by the reference symbol 5 designate the direction of the incident light, for example of the incident sunlight. Furthermore, in the exemplary embodiments, the layer arrangements are accordingly arranged on the outer side of the transparent pane 4 in a manner facing in the direction of the incident light 5. It is obvious to a person skilled in the art, however, that the layer arrangements can also analogously be fitted on the inner side of the pane 4 or be laminated into the pane 4 in the case of a glass pane composite.

In accordance with a first preferred exemplary embodiment according to FIG. 1, the layer arrangement for darkening the transparent pane 4 comprises a first photovoltaic layer 1, which represents the layer right at the front, or the topmost layer in FIG. 1, in the direction of the incident light 5. The entire layer arrangement is formed as a thin film, for example, which can easily be adhesively bonded onto the transparent pane 4 or be laminated or embedded into the transparent pane 4.

The first photovoltaic layer 1, that is to say the solar cell layer 1 essentially serving as an energy converter, is preferably composed of one or more semiconductor elements, such as, for example, of silicon, germanium or the like. The semiconductor elements are suitably doped in a customary manner such that a predetermined percentage of the incident light 5 is converted into electrical energy or into thermal energy. The functioning of such solar cells together with energy storing device is sufficiently known in the prior art, such that a detailed description thereof can be dispensed with.

The first photovoltaic layer 1 is furthermore formed in such a way that it has a high degree of light absorption, in order to convert a predetermined proportion of the incident light 5 into electrical energy.

As can be seen in FIG. 1, a second photovoltaic layer 2 is arranged behind the first photovoltaic layer 1 in the direction of the incident light 5, and advantageously likewise has a high degree of light absorption and a high degree of light reflection in order, firstly, to convert a predetermined proportion of the incident light 5 which passes through the first photovoltaic layer into electrical energy and in order, secondly, to reflect a proportion of the incident light 5 in the direction of the first photovoltaic layer 1, such that the first photovoltaic layer 1 can additionally absorb a proportion of this radiation reflected by scattering or refraction and convert it into electrical energy. This increases the efficiency of the layer arrangement.

The second photovoltaic layer 2, analogously to the first photovoltaic layer 1, is preferably formed from one or more semiconductor elements, in which case, for example, suitable doped silicon or germanium can again be used.

The photovoltaic layers 1 and 2 in each case serve on the one hand for light absorption for generating electrical energy or thermal energy and on the other hand for darkening the transparent pane 4.

Preferably, in particular the charge carrier layers of the two photovoltaic layers 1 and 2 are in each case produced by means of nano- and/or picotechnology and/or even smaller technologies, that is to say that at least the p-n layers of the photovoltaic layers 1 and 2 have nano- and/or picoparticles and/or even smaller particles. As a result, a larger proportion of the incident radiation 5 can be absorbed compared with customary microtechnology on account of the smaller dimensions of the particles and of the resulting smaller interspace between the particles, such that the efficiency of the photovoltaic layers 1 and 2 can be increased in comparison with the microtechnology generally used. It is obvious to a person skilled in the art that picotechnology or else microtechnology, if appropriate, can also be used instead of nanotechnology, or that a plurality of layers having mutually different particle configurations can be provided successively. Furthermore, it is possible to use layers which have a mixture of femto-, pico-, nano- and/or microparticles or of even smaller particles. The photovoltaic layers 1 and 2 are advantageously formed in such a way that the efficiency, that is to say the electrical energy generated, is optimized.

In accordance with the first exemplary embodiment according to FIG. 1, the layer arrangement has an active insulation layer 3 behind the second photovoltaic layer 2 in the direction of the incident radiation 5. The active insulation layer 3 is preferably constructed from one or more semiconductor elements and has for example polycarbonate or silicon dioxide and in each case highly depleted space charge zones.

Preferably, the active insulation layer 3 is formed in the form of an organic light emitting diode (OLED), the organic material having no free charge carrier in the undoped state. Consequently, materials of this type are good insulators. An organic light emitting diode (OLED) generally comprises a substrate, an anode, an organic emitter layer and a cathode, in which case the degree of absorption or the degree of current generated and thus the degree of darkening can be varied by application of a suitable electrical voltage. If a voltage is applied in such a way that the current flowing in the OLED layer 3 is reduced, the degree of darkening of the layer 3 is correspondingly increased. Consequently, the degree of darkening of the OLED layer 3 can be correspondingly controlled by introduction of a suitable voltage.

By way of example, the active insulation layer 3 is formed as an OLED composed of suitable thin-film layers. The latter can be produced even at low temperatures and therefore simply and cost-effectively.

By way of example, the active insulation layer 3 can also be produced by means of nanotechnology or picotechnology and correspondingly have nano- or picoparticles in order to correspondingly improve the properties of the insulation layer 3.

Preferably, a control device (not illustrated) is provided in the layer arrangement, for example a customary control circuit which is fabricated as a thin film and which uses the electrical energy generated by the photovoltaic layers 1 and/or 2 for driving the active insulation layer 3 for changing the degree of darkening thereof. By way of example, the degree of darkening of the OLED layer 3 can be controlled by application of a suitable voltage depending on the incident light intensity, the incident radiation 5 being detected and evaluated in this case. Furthermore, control can be effected by the motor vehicle user in such a way that said user manually sets the degree of darkening of the layer arrangement by setting a suitable voltage at the OLED layer 3.

In order to reduce the inherent consumption and the high temperature development of the photovoltaic layers 1 and 2, it is also conceivable for these two layers likewise to be formed from an organic light emitting diode (OLED), the degree of absorption for generating electrical energy preferably having a high value in this case.

FIG. 2 illustrates a cross-sectional view of a layer arrangement applied on a transparent pane 4 in equivalence with a second preferred exemplary embodiment of the present invention. If nothing to the contrary is explained below, the explanations given in accordance with the first exemplary embodiment are analogously applicable to the second exemplary embodiment.

In contrast to the first exemplary, the layer arrangement in accordance with the second exemplary embodiment has two successive first photovoltaic layers 1a and 1b. It is obvious to a person skilled in the art that it is also possible for more than two first photovoltaic layers to be provided one behind another. A plurality of first photovoltaic layers bring about an increase in the degree of light absorption of the entire layer arrangement and thus an increase in the electrical energy generated. Advantageously, the electrical energy generated is not used exclusively for the control of the degree of darkening of the active insulation layer, but rather can for example be stored in an energy store or be used directly for operating further components of the motor vehicle.

Even though only one second photovoltaic layer 2 is illustrated in FIG. 2, it is likewise obvious to a person skilled in the art that it is also possible for two or more second photovoltaic layers 2 to be provided in order to form the entire layer arrangement having the desired absorption and reflection properties. Furthermore, it is also possible for a plurality of first and second layers to be arranged alternately or in any desired sequence.

As is additionally illustrated in FIG. 2, in contrast to the first exemplary embodiment, two active insulation layers 3a and 3b are provided successively. It is once again obvious to a person skilled in the art that it is also possible for more than two active insulation layers to be provided.

The insulation layers 3a and 3b are preferably formed analogously to the first exemplary embodiment in each case as organic light emitting diodes (OLED) and are in each case driven by a common or separate control device with the energy generated by the photovoltaic layers 1a, 1b and/or 2 in such a way that overall they obtain a desired degree of darkening.

Although the present invention has been described above on the basis of preferred exemplary embodiments, it is not restricted thereto, but rather can be modified in diverse ways.

### LIST OF REFERENCE SYMBOLS

1 first layer
1a front first layer
1b rear first layer
2 second layer
3 active insulation layer
3a front active insulation layer
3b rear active insulation layer
4 transparent pane
5 incident light

1. A layer arrangement for darkening a transparent pane in particular a motor vehicle pane, in order to afford protection from incident light, comprising:
at least one first photovoltaic layer with a high degree of light absorption;
at least one second photovoltaic layer with a high degree of light absorption and a high degree of light reflection, arranged behind the at least one first photovoltaic layer in the direction of the incident light;
at least one active insulation layer with an electrically variable degree of darkening, arranged behind the at least one second photovoltaic layer in the direction of the incident light; and
a control device for electrically controlling the degree of darkening of the at least one active insulation layer using the electrical energy generated by the at least one first photovoltaic layer and/or the at least one second photovoltaic layer, the control device being provided in the layer arrangement as thin film fabricated control circuit.

2. The layer arrangement of claim 1, characterized in that a plurality, for example two or three, of first photovoltaic layers are provided successively in order to increase the total quantity of light absorbed.

3. The layer arrangement of claim 1, characterized in that a plurality, for example two or three, of second photovoltaic layers are provided successively in order to increase the total quantity of light absorbed and reflected.

4. The layer arrangement of claim 1, characterized in that the at least one first photovoltaic layer and/or the at least one second photovoltaic layer are in each case composed of at least one suitably doped semiconductor material, for example a doped silicon, doped germanium or the like.

5. The layer arrangement of claim 1, characterized in that the at least one first photovoltaic layer and/or the at least one second photovoltaic layer in each case have a nano- and/or picomaterial.

6. The layer arrangement of claim 1, characterized in that a plurality, for example two or three, of active insulation layers are provided successively in order to increase the total degree of darkening.

7. The layer arrangement of claim 1, characterized in that the at least one active insulation layers is formed as a semiconductor layer, preferably in the form of an organic light emitting diode (OLED) an LED, an LCD or a mixture of the OLED, LED and LCD or the like.

8. The layer arrangement of claim 1, characterized in that the at least one active insulation layer has a nano- and/or picomaterial and/or an even smaller material.
